(19) United States
(12) Patent Application Publication
(10) Pub. No.: US 2009/0268503 A1
(43) Pub. Date: Oct. 29, 2009

(54) NON-VOLATILE MEMORY BITCELL

(76) Inventors: Cornelius Petrus Elisabeth Schepens, Beuningen (BE); Robertus P. Van Kampen, s-Hertogenbosch (NL)

Correspondence Address: PATTERSON & SHERIDAN, L.L.P., 3040 POST OAK BOULEVARD, SUITE 1500, HOUSTON, TX, 77056, US

(21) Appl. No.: 12/441,121

(22) PCT Filed: Sep. 13, 2007
(86) PCT No.: PCT/GB2007/003470

§ 371 Date: Mar. 12, 2009

(30) Foreign Application Priority Data
Sep. 13, 2006 (GB) 0618045.9

(51) Int. Cl. G11C 5/06; G11C 11/50

(52) U.S. Cl. 365/72; 365/164

(57) ABSTRACT

A non-volatile memory bitcell which comprises a first bistable cantilever module and a second bistable cantilever modules. The bistable cantilever modules have a shared output terminal and each has an input terminal and two actuating terminals. The first and second cantilever modules are arranged such that their states are complementary. The memory bitcell further includes buffering means arranged to prevent the flow of current from the shared output terminal and further arranged to indicate the states of the first and second cantilever modules.

The present invention is related to the field non-volatile memory based on mechanical nanotechnology.

Current non-volatile memory architectures, such as Erasable Programmable Read-Only Memory (EPROM), have slow read speeds compared to those of Synchronous Random Access Memory (SRAM). This makes them particularly unsuitable for applications requiring high reading bandwidth. These applications may include micro-controllers running at more than 50 megahertz, Field Programmable Gate Arrays (FPGAs) or System On Chip (SOC) Application Specific Integrated Circuits (ASICs).

In order to remedy this situation, prior art memory architectures have been developed comprising wider memory arrays having more output signals. Although these memory devices read at slower speeds, they read more information from the memory in a read cycle. However, this solution requires an increase in power consumption and still suffers from a delay in read operation speed if data is not ordered in a consecutive manner. Thus, if data is not ordered consecutively in the array, an increase in memory array width may simply cause an increase in the amount of unwanted data being read.

In order to provide a solution to the problem of fetching unwanted data, cache systems have been developed which use smaller width memory arrays coupled to non-volatile memories in order to reduce the amount of unwanted data that is pre-fetched, thereby reducing overall read time.

These cache systems are based on volatile SRAM memories and therefore have reading speeds which are higher than known non-volatile memories. However, cache memories require more power and, when a system requires specific data, the data in the cache is always read first. When the data is not found in the cache (i.e. a “cache miss”), the system will have performed an extra read step, thereby resulting in slower total read speeds.

Moreover, small microcontrollers do not have the space necessary to use complex cache memory units and must therefore simply operate at lower frequencies.

Thus, there exists a need for a non-volatile memory cell that can achieve read speeds which are comparable to SRAM read speeds, that can be manufactured based on known Complementary Metal Oxide Substrate processes and that is not dependant on external cache memory.

In order to solve the problems associated with the prior art, the present invention provides a non-volatile memory bitcell which comprises:

a first bistable cantilever module and a second bistable cantilever
module having a shared output terminal and each having an input terminal and two actuating terminals, wherein the first and second cantilever modules are arranged such that their states are complementary; and

buffering means arranged to prevent the flow of current from the shared output terminal and further arranged to indicate the states of the first and second cantilever modules.

The buffering means may be a transistor where the input terminal of the transistor is connected to the shared output terminal of the cantilever modules.

The buffering may be a first inverter comprising an n-channel transistor and a p-channel transistor connected in series and the input of the inverter is connected to the shared output terminal of the cantilever modules.

The buffering means may further comprise:

a second inverter which includes an n-channel transistor and a p-channel transistor connected in series and, wherein the input of the second inverter is connected to the shared output terminal of the cantilever such that the output of the second inverter is complementary to the output of the first inverter.
The output of the buffer may be connected to the common terminal of a transistor.

The present invention further provides a memory device comprising:

a plurality of non-volatile memory bitcells in accordance with any of the preceding claims.

As will be apparent to one skilled in the art, the present invention provides several advantages over the prior art. One advantage is that the memory cell of the present invention has speeds which are comparable to those of Static Random Access Memory modules. Another advantage which is provided by the present invention is that the present invention may be manufactured based on known Complementary Metal Oxide Substrate (CMOS) processes, with the addition of a few process steps. Moreover, the memory module manufactured in accordance with the present invention are not dependent on external cache memories and are therefore smaller, easier to design and less costly to manufacture. Yet another advantage of the present invention is that there is no dynamic signal running through the cantilever and therefore very little risk that the cantilever can be damaged through use of the memory device. Furthermore, because the signal-to-noise ratio of transistors decreases as transistors are made smaller, current SRAM bitcells have a threshold size at which a low signal-to-noise ratio may cause a bitcell to lose its value. Dissimilarly, because the bitvalue of the present invention is stored in the cantilevers, the signal-to-noise ratios of the transistors do not effect the operation of the bitcell, thereby permitting, by using the smallest transistor available within the process technology used, the provision memory bitcells that are smaller than SRAM bitcells.

An example of the present invention will now be described with reference to the accompanying drawings, in which:

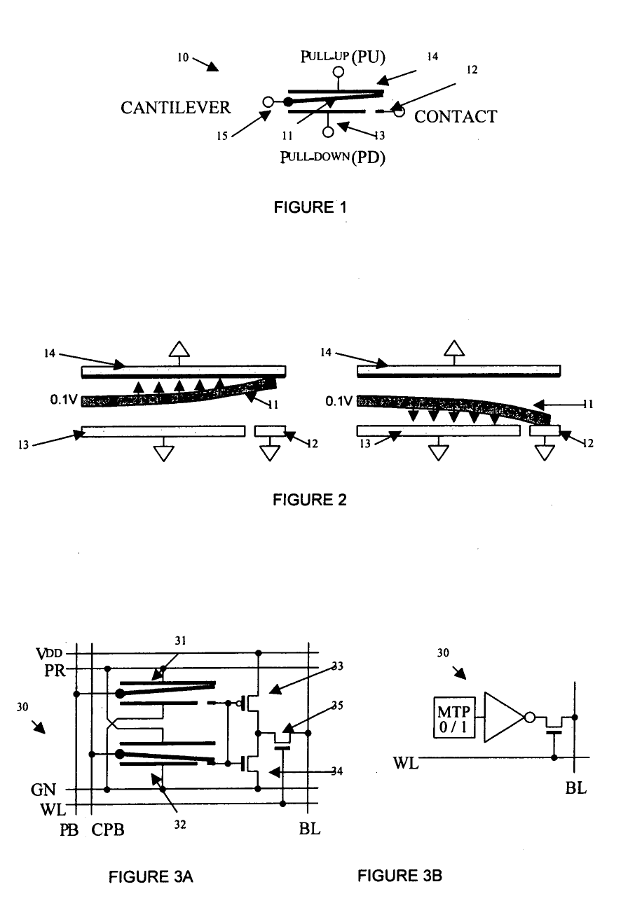

FIG. 1 shows a schematic view of a 4-terminal Multiple Times Programmable (MTP) cantilever memory bitcell in accordance with the prior art;

FIG. 2 shows a diagram of the resulting electrostatic forces acting on the cantilever of the memory bitcell of FIG. 1 during readout;

FIG. 3A shows a schematic view of a high-speed asynchronous readout memory bitcell in accordance with a first example of the present invention;

FIG. 3B shows a high level schematic representation of the memory bitcell of FIG. 3A;

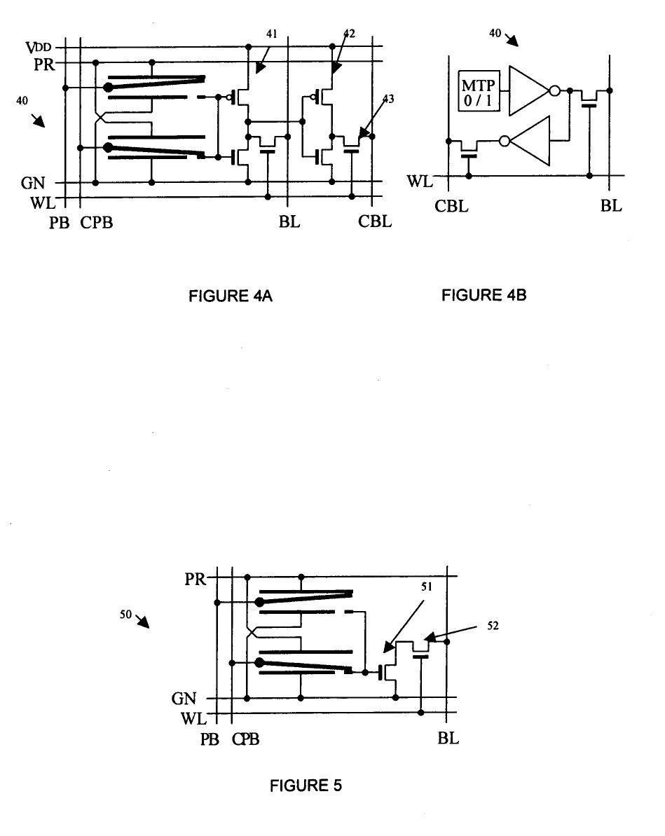

FIG. 4A shows a schematic view of a high-speed asynchronous readout memory bitcell in accordance with a second example of the present invention;

FIG. 4B shows a high level schematic representation of the memory bitcell of FIG. 4A;

FIG. 5 shows a schematic view of a high-speed synchronous readout memory bitcell in accordance with a third example of the present invention;

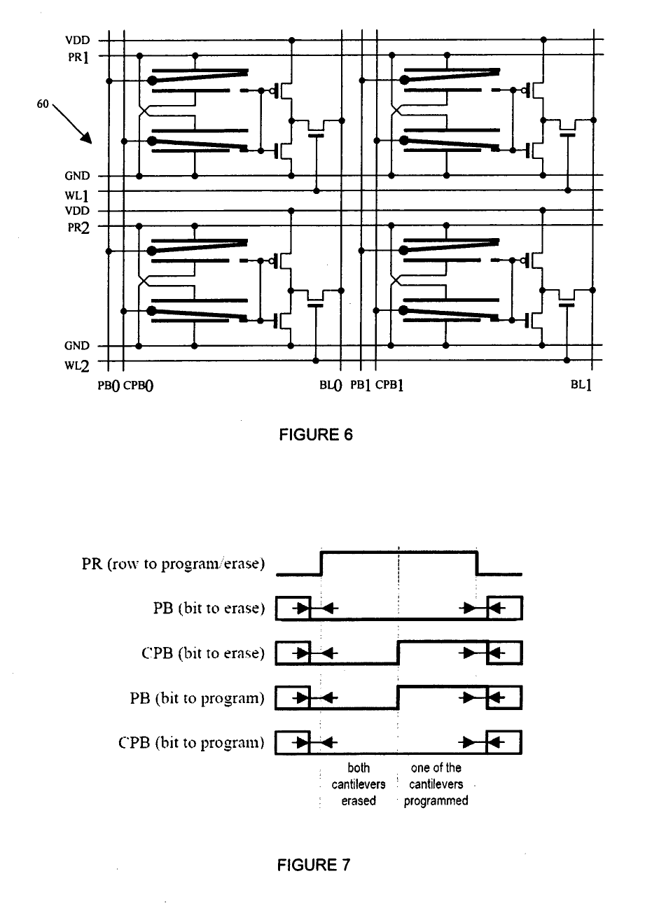

FIG. 6 shows a schematic view of an asynchronous multiple times programmable memory array architecture in accordance with one example of the present invention;

FIG. 7 shows a timing diagram of the programming and erasing operations of a memory bitcell in accordance with one example of the present invention;

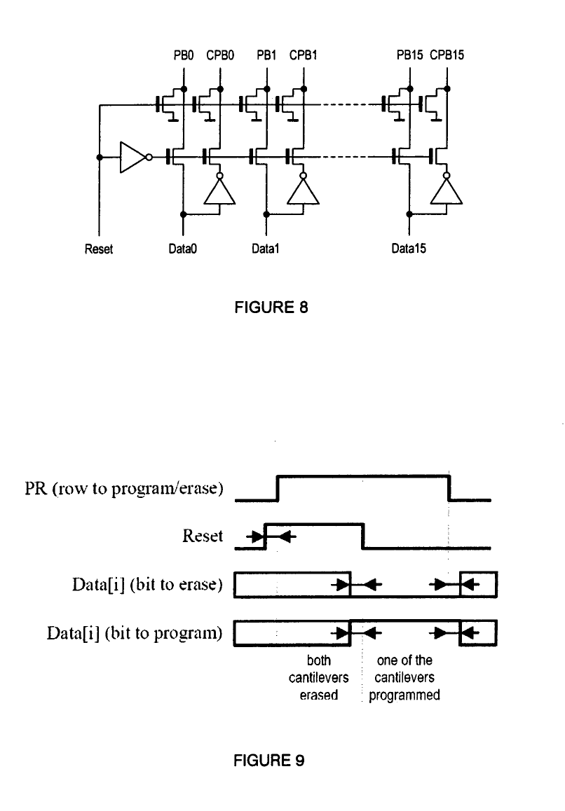

FIG. 8 shows a schematic diagram of a programming interface circuit for programming a memory bitcell array in accordance with one example of the present invention; and

FIG. 9 shows a timing diagram of the programming and erasing operations of a memory bitcell array in accordance with one example of the present invention.

FIG. 1 shows a schematic view of a 4-terminal Multiple Times Programmable (MTP) cantilever memory bitcell 10 in accordance with the prior art. The memory bitcell 10 contains a moveable bistable cantilever 11 that can be pulled to either a first or a second position using a pull-up electrode 14 and pull-down electrode 13. The pull-up electrode 14 is covered with an insulating layer so that when the cantilever 11 is pulled-up, no current can flow through it. When the cantilever 11 is pulled-down, it is put into contact with the contact terminal 12, which is also electrically conductive. Once the cantilever 11 is in contact with either the pull-up electrode 14 or the contact terminal 12, it is held in place via stiction-forces (i.e. metal-to-metal bonding, Van der Waals and Casimir forces). In order to move the cantilever 11 from one electrode to the other, the electrostatic forces created by the application of a specific voltage to the pull-up electrode 14, the pull-down electrode 13 and the cantilever 11 must overcome these stiction forces.

FIG. 2 show the resulting electrostatic forces acting on the cantilever 11 during a read operation of the bitcell 10. Because the pull-up electrode 14 and pull-down electrode 13 are at OV during a read operation, the resulting electrostatic force is always pulling the cantilever 11 tighter against the closest electrode (i.e. towards the pull-up electrode 14 for an erased cell and towards the pull-down 13 electrode for a programmed cell).

In order to read the memory bitcell 10 of the prior art, a reference voltage is applied to the cantilever terminal 15 and the current through the contact terminal 12 is measured. However, the problem with this prior art memory bitcell 10 is that having excessive amounts of current flowing through it may damage the cantilever 11. Moreover, because the contact electrodes of these memory bitcells 10 are typically connected to transistors (not shown), the only way to increase the read speed (i.e. to generate a current flowing through the contact terminal 12 by applying a reference voltage to the cantilever terminal 15) is to increase the reference voltage in order to generate a higher current through cantilever, thereby permitting a sense amplifier to sense the current quicker. Thus, one of the problems faced is how to increase the speed of the read operation without damaging the cantilever 11 itself.

In reference to FIG. 3A, an example memory cell 30 comprises a first 4-terminal MTP cantilever module 31 and a second 4-terminal MTP cantilever module 32. The cantilever terminal (or input terminal) of the first cantilever module 31 is connected to a Programming Bitline (PB) and the cantilever terminal of the second cantilever module 32 is connected to a Complimentary Programming Bitline (CPB). At any point during a read operation of the circuit, the signal on the PB will be the logical inverse of the signal on the CPB (e.g. if PB is HIGH, then CBP will be LOW). The pull-up terminals of both the first cantilever module 31 and the second cantilever module 32 are connected to the Programme Line (PR). The pull-down terminals of both the first cantilever module 31 and the second cantilever module 32 are connected to ground (GND). The contact terminals (or output terminals) of both the first cantilever module 31 and the second cantilever module 32 are connected to both a p-channel transistor 33 and an n-channel transistor 34. The drains and sources of the p-channel transistor 33 and the n-channel transistor 34 are connected in series from VDD to GND. Finally, a wordline transistor 35 is added to pass the output of the memory bitcell onto the bitline when the memory bitcell is selected. FIG. 3B shows a high level schematic representation of the memory bitcell 30 of FIG. 3A.

As mentioned above, the cantilever of the first cantilever module 31 is either connected to the contact electrode of the first cantilever module 31, which is itself connected to the gates of the n-channel transistor 34 and the p-channel transistor 33, or, it may be floating. Providing a second cantilever module 32 is useful in this respect because it is undesirable to have the gate of either transistor floating. The provision of two cantilever modules which are complementarily programmed ensures that, at any one time, one of the two cantilevers will be connected to the gates of the transistors.

In read mode, the cantilever terminal of one of either the first cantilever module 31 or the second cantilever module 32 is connected to GND and the cantilever terminal of the other cantilever module is connected to VDD. Thus, the gates of the transistors will either be connected to GND or VDD, depending on the non-volatile state of both complementary cantilevers. Since the cantilevers are connected to the gates of the transistors, there will effectively be no current flowing through either cantilever. Only during programming will there be a short pulse of minor current to load up the gate of the two transistors. Finally, either the pull-up transistor 33 or the pull-down transistor 34 of the inverter will sink the current from the bitline when the wordline transistor 35 is switched on.

The read speed will be determined by the switching speed of the transistor. The read operation of this memory bitcell can therefore reach speeds that are similar to those of current SRAM cells.

It is possible to increase the speed of the read operation further by adding a complementary bitline (CBL) to the circuit of FIG. 3A and feeding the complimentary bitline into the sense amplifier, as a sense amplifier between to complimentary signals is generally faster than a sense amplifier with only one bitline signal. FIG. 4A shows a memory bitcell 40 which comprises the circuit of FIG. 3A and a second inverter circuit 42 connected between the output of the inverter circuit 41 of the bitcell of FIG. 3A and a second wordline transistor 43 connected to the complementary bitline. In this embodiment, the resulting critical timing path during reading is identical to the timing path in an SRAM bitcell. Thus, this embodiment provides a bitcell with read speeds which are identical to those of an SRAM bitcell having transistors of identical dimensions. FIG. 4B shows a high level schematic representation of the memory bitcell of FIG. 4A.

With reference to FIG. 5, another example memory bitcell 50 is shown where the p-channel transistor 33 of the previous example has been omitted. This example is ideally suited for applications where active push-pull configurations are not required. Such applications may include fast synchronous memory architectures where bitlines can be pre-charged during address decoding. This embodiment provides a memory with a very small area and a fast reading speed. The two cantilever modules in this embodiment are placed on top of each other, with the two transistors underneath. FIG. 6 shows an array 60 of memory bitcells similar to the one shown in FIG. 3A. The array uses a push-pull driver with a single bitline per cell and could be used in a memory array operating in an asynchronous read-mode.

The memory bitcell can only change states by setting the programming line PR to Vprog. The state of the cantilever is determined by the voltage applied to the cantilever terminal, as follows. When Vcant=0, the cantilever is erased and when Vcant=Vprog, the cantilever is programmed.

Because the complementary cantilevers in each cantilever module are programmed in an opposite state, the voltages applied to each pair of cantilevers are complementary.

If a cantilever in a given memory bitcell is programmed before the complementary cantilever in the same memory bitcell is erased, these cantilevers will have the programming voltage across their cantilever terminals, which may damage or destroy the cantilever and/or the contact of the output terminal. A similar situation can occur immediately after the cantilevers have been released, since both cantilevers can be in the programmed position, effectively connecting the PB and CPB lines through the cantilevers. To avoid this situation, both cantilevers should be erased before programming the desired state, as is shown in the timing diagram of FIG. 7.

Upon activation of the programming line PR, all cells connected to this programming line will change their state according to the voltages set on the programming bitlines PB and CPB. Therefore, all the programming bitlines must have been set to the correct value before the programming operation. One possible implementation of an interface circuit which is designed to achieve this is shown in FIG. 8.

As long as the reset is high, the programming bitlines are at GND such that the cantilevers are erased upon the activation of the programming line PR. At some point during this reset phase, the correct data must be set on the Data[i] inputs. Once the reset is released, the complimentary voltages appear on the programming lines, so that the cells are programmed in their desired state.

In the case of a system which comprises a plurality of small memory modules, the plurality of small memory modules can share the programming lines. Only the memories having activated programming lines PR will be programmed with the set data. This will reduce the total area used by these memories.

During normal read operation, the cantilevers in a bitcell are at opposite static potentials (PBi=GND and CPBi=VDD for i=[1, 2, 3, . . . ]), as in FIGS. 6 and 8) and only during an erase and program cycle will these signals change, according to the scheme presented in FIG. 7. FIG. 8 shows a simple schematic of how such signal scheme can be obtained. This is achieved using the signals found in the timing diagram of FIG. 9. Thus, all data inputs Data [i] and resets will be set to LOW in read mode. The combination of PR and RESET signals define the respective erase and program modes of the memory.

When the memory bitcell 30 is in the programmed state (first cantilever module 31 programmed and second cantilever module 32 erased), the input of the inverter is LOW and the output of the inverter is HIGH. Therefore, the bitline is actively pulled HIGH when the wordline is activated.

When the memory bitcell 30 is in the erased state (i.e. first cantilever module 31 erased and second cantilever module 32 programmed), the input of the inverter is HIGH and the output of the inverter is LOW. Therefore, the bit line is actively pulled LOW when the wordline is activated.

The program and erase procedures of this architecture are robust because the memory bitcells will only change state once the selected PR is set HIGH. Either the PBi or CPBi signal will change value when PR is set HIGH, depending on whether the memory bitcell will be programmed with a 1 or 0.

Thus, both the cantilevers and the inverters are not in the critical path of the read operation. Only the word-line transistor within the memory bitcell is in the critical path of the read operation. This also implies that the read speed of a memory architecture with six transistors can reach the exact reading speed of a standard fast SRAM memory with 6 transistors.

The proposed memory architectures for non-volatile memories with much higher read speeds all require 2 cantilevers. For the examples with 2 and 3 transistors, the cell size will be determined by the size of the 2 cantilevers. The size of the 6 transistor example will most likely be determined by the size of the 6 transistors and not the two cantilevers.

1. A non-volatile memory bitcell comprising:
a first bistable cantilever module and a second bistable cantilever module having a shared output terminal, and each bistable cantilever module having an input terminal and two actuating terminals wherein the first and second bistable cantilever modules are arranged such that their states are complementary; and
a first inverter comprising:
a first transistor coupled to the shared output terminal of the first bistable cantilever module and the second bistable cantilever module; and
a second transistor coupled to the first transistor and a bitline.

2. (canceled)

3. The non-volatile memory bitcell of claim 7, wherein the first transistor comprises an n-channel transistor, the third transistor comprises a p-channel transistor connected in series with the first transistor, and the input of the first inverter is connected to the shared output terminal of the first and second bistable cantilever modules.

4. The non-volatile memory bitcell of claim 3 further comprising:
a second inverter which includes an n-channel transistor and a p-channel transistor connected in series and, wherein the input of the second inverter is connected to the output terminal of the first inverter such that the output of the second inverter is complementary to the output of the first inverter.

5. (canceled)

6. A memory device comprising:
a plurality of non-volatile memory bitcells of claim 1.

7. The non-volatile memory bitcell of claim 1, wherein the first inverter additionally comprises a third transistor coupled to the shared output of the first bistable cantilever module and the second bistable cantilever module.

8. A memory device comprising:
a plurality of non-volatile memory bitcells of claim 3.

9. A memory device comprising:
a plurality of non-volatile memory bitcells of claim 4.

10. A memory device comprising:
a plurality of non-volatile memory bitcells of claim 7.

11. A non-volatile memory bitcell, comprising:
a first bistable cantilever module having a first pull up electrode, a first pull down electrode coupled to ground, a first cantilever and a first output terminal;
a second bistable cantilever module having a second pull up electrode, a second pull down electrode coupled to ground, a second cantilever and a second output terminal coupled to the first output terminal;
a programming bitline coupled to the first cantilever;
a programme line coupled to the first pull up electrode and the second pull up electrode;
a first inverter coupled to the first output terminal and the second output terminal, the first inverter comprising:
a first transistor coupled to one or more of the first output terminal and the second output terminal; and
a second transistor coupled to the first transistor and a bitline.

12. The non-volatile memory bitcell of claim 11, further comprising a complementary programming bitline coupled to the second cantilever.

13. The non-volatile memory bitcell of claim 12, wherein the first transistor is coupled to the second output terminal, the bitcell further comprising a third transistor coupled to the second output terminal, wherein the first transistor and the third transistor are connected in series.

14. The non-volatile memory bitcell of claim 13, further comprising a second inverter, the second inverter comprising at least two transistors.

15. The non-volatile memory bitcell of claim 14, wherein at least two transistors of the second inverter are connected in series.

16. The non-volatile memory bitcell of claim 15, wherein at least one transistor of the second transistor is a wordline transistor.

17. The non-volatile memory bitcell of claim 13, wherein the first transistor is an n-channel transistor, the second transistor is a wordline transistor and the third transistor is a p-channel transistor.

18. The non-volatile memory bitcell of claim 11, wherein the first transistor is an n-channel transistor and is coupled to the first output terminal and the second output terminal.

19. The non-volatile memory bitcell of claim 18, further comprising a complementary programming bitline coupled to the second cantilever.

20. The non-volatile memory bitcell of claim 19, wherein the second transistor is a wordline transistor.

21. A memory device, comprising:
a first non-volatile memory bitcell comprising:
a first bistable cantilever module having a first pull up electrode, a first pull down electrode coupled to ground, a first cantilever and a first output terminal;
a second bistable cantilever module having a second pull up electrode, a second pull down electrode coupled to ground, a second cantilever and a second output terminal coupled to the first output terminal;
a first programming bitline coupled to the first cantilever;
a first programme line coupled to the first pull up electrode and the second pull up electrode;
a first inverter coupled to the first output terminal and the second output terminal, the first inverter comprising:
a first transistor coupled to the first output terminal and the second output terminal;
a second transistor coupled to the first output terminal and the second output terminal; and
a third transistor coupled to the first transistor, the second transistor and a first bitline; and
a second non-volatile memory bitcell comprising:
a third bistable cantilever module having a third pull up electrode, a third pull down electrode coupled to ground, a third cantilever coupled to the first programming bitline and a third output terminal;
a fourth bistable cantilever module having a fourth pull up electrode, a fourth pull down electrode coupled to ground, a fourth cantilever and a fourth output terminal coupled to the third terminal output;
a second programme line coupled to the third pull up electrode and the fourth pull up electrode;
a second inverter coupled to the third output terminal and the fourth output terminal, the second inverter comprising:
a fourth transistor coupled to the third output terminal and the fourth output terminal;
a fifth transistor coupled to the third output terminal and the fourth output terminal; and
a sixth transistor coupled to the fourth transistor, the fifth transistor and the first bitline.

22. The memory device of claim 21, further comprising a complementary programming bitline coupled to the second cantilever and the fourth cantilever, and wherein the first transistor and the second transistor are connected in series and the fourth transistor and the fifth transistor are connected in series.
